(19) United States
(12) Patent Application Publication
(10) Pub. No.: US 2011/0248341 A1
(43) Pub. Date: Oct. 13, 2011

(54) CONTINUOUS ASYMMETRICALLY SLOPED SHALLOW TRENCH ISOLATION REGION

(76) Inventor: Matthew Alan Ring, Saco, ME (US)

(21) Appl. No.: 13/085,191

(22) Filed: Apr. 12, 2011

Related U.S. Application Data
(60) Provisional application No. 61/322,999, filed on Apr. 12, 2010.

(51) Int. Cl. H01L 29/78

(52) U.S. Cl. 257/335; 257/E29.255

(57) ABSTRACT

This document discusses, among other things, a semiconductor device, and a method of forming a semiconductor device, having a shallow trench isolation (STI) region including a continuous, asymmetrically sloped sidewall.

### CLAIM OF PRIORITY

This application claims the benefit of priority under 35 U.S.C. §119(e) of Matthew Alan Ring, U.S. Provisional Patent Application Ser. No. 61/322,999, entitled “ASYMMETRICALLY SLOPED SHALLOW TRENCH ISOLATION REGION,” filed on Apr. 12, 2010 (Attorney Docket No. 2921.046PRV), which is hereby incorporated by reference herein in its entirety.

### BACKGROUND

A transistor is a semiconductor device used to switch or amplify electronic or electrical signals. Early transistor usage was dominated by Bipolar Junction Transistor (BJT) devices. The BJT is a three terminal transistor constructed of doped semiconductor material, popular due to their ease of manufacture and speed. As demand for high-speed, low-cost, small-size digital components increased, Metal Oxide Field Effect Transistor (MOSFET) devices became more prevalent. The MOSFET typically includes a metal or polysiticon gate separated from a semiconductor region by an insulator. The semiconductor region generally includes a substrate of a first conductivity type, and a source region and drain region of a second different conductivity type located on either side of the semiconductor region, under the insulator.

MOSFET devices can be categorized, generally, as n-channel or p-channel devices, or as enhancement-mode or depletion-mode devices. The enhancement-mode MOSFET includes a drain region and a source region isolated by the substrate. In the enhancement MOSFET, as voltage is applied to the gate, a channel forms on the surface of the semiconductor region between the drain and the source, allowing current to flow between the source and the drain.

In contrast, the depletion MOSFET includes a coupled source and drain region extending below the gate. Here, as voltage is applied to the gate, a depletion region forms under the insulator, narrowing the coupled region between the source and the drain, reducing the ability for current to flow between the source and the drain.

The terms “n-channel” and “p-channel” refer to the type of charge carrier providing conduction between the source region and the drain region, An “n-channel” or “NMOS” device uses majority conduction using electrons when the device is biased into conduction, Similarly, “p-channel” or “PMOS” refer to conduction via the migration of “holes.” Unlike bipolar junction transistors (BJTs), MOSFET devices primarily use majority carriers.

Different types of MOSFET devices can be co-integrated on a single monolithic substrate, such as by fabricating one or more wells of a first conductivity type (e.g,, n type) within a substrate of the opposite conductivity type (e,g., p type). Such integrated combinations are called complimentary metal-oxide-semiconductor (CMOS) integrated circuits.

CMOS integrated circuits are usually more cost effective to manufacture as compared to bipolar technology. Further, CMOS integrated circuits can be planar, including processing primarily involving one surface of a substrate or wafer. Such planar processing can include, for example, ion implantation, diffusion, deposition, oxidation, epitaxy, one or more photolithographic techniques, or one or more other process steps. Multiple MOSFETs, among other devices such as MOS capacitors or resistors, can be fabricated and interconnected on a single monolithic substrate. Such integrated assemblies can include anywhere from a handful of devices to beyond hundreds of millions of individual devices.

One or more shallow trench isolation (STI) regions can be formed by etching one or more trenches in a substrate of a device or between device regions to reduce current leakage or otherwise provide isolation or protection of proximate devices or device regions on the substrate. In an LDMOS device, an STI region located between a drain and source region of the device can increase the resistance between the drain and the source, increasing the breakdown voltage of the device.

### OVERVIEW

This document discusses, among other things, a semiconductor device, and a method of forming a semiconductor device, having a shallow trench isolation (STI) region including a continuous asymmetrically sloped sidewall.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally examples of first and second shallow trench isolation (STI) regions of a lateral double-diffused metal oxide semiconductor (LDMOS) or other device.

FIG. 2 illustrates generally an example of an asymmetrically sloped shallow trench isolation (STI) region of a lateral double-diffused metal oxide semiconductor (LDMOS) or other device.

FIGS. 3-8 illustrate generally example fabrication steps for forming an asymmetrically sloped STI region on a device

### DETAILED DESCRIPTION

The present inventor has recognized, among other things, a shallow trench isolation (STI) region of a device, such as a lateral double-diffused metal oxide semiconductor (LDMOS) device, having one or more continuous, asymmetrically sloped sidewalls. The continuous (e.g., non-stepped), asymmetrically sloped STI region can produce a device having, for example, lower levels of hot carrier degradation than a conventional STI device (providing improved hot carrier reliability lifetimes), a lower drain to source on-resistance (R_{DSon}) than a conventional STI device, or a lower cost to have an R_{DSon} advantage in an LDMOS device as compared to a stepped-STI trench solution. Further, the present inventors have recognized that high packing density of low voltage devices can be maintained using steeper sidewall isolation proximate the low voltage devices or in the area of high packing density.

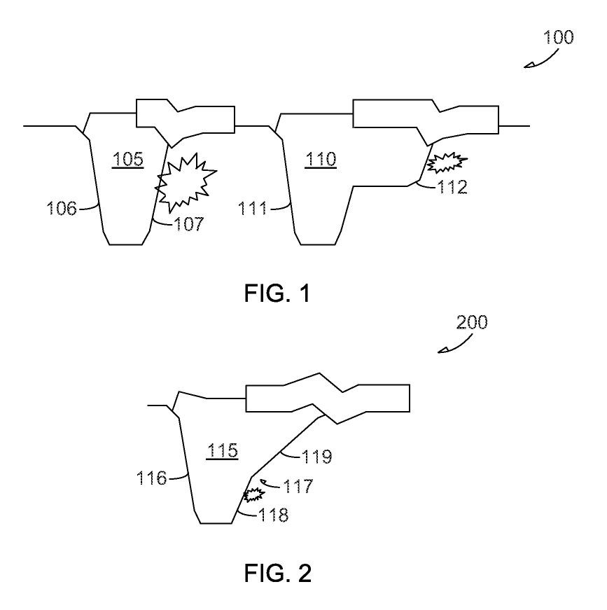

FIG. 1 illustrates generally examples of first and second STI regions 105, 110 of an LDMOS device 100. In other examples, the LDMOS device 100 can include one or more other devices having an STI region.

In an example, the first STI region 105 includes a trench having steeply sloped, substantially uniform first and second sidewalls 106, 107 having a large amount of hot carrier degradation. The second STI region 110 includes a trench having one steeply sloped sidewall 111 and one stepped, non-continuous sloped sidewall 112. In certain examples, a reduction in sidewall slope can lead to a reduced device off-current or lower hot carrier degradation.

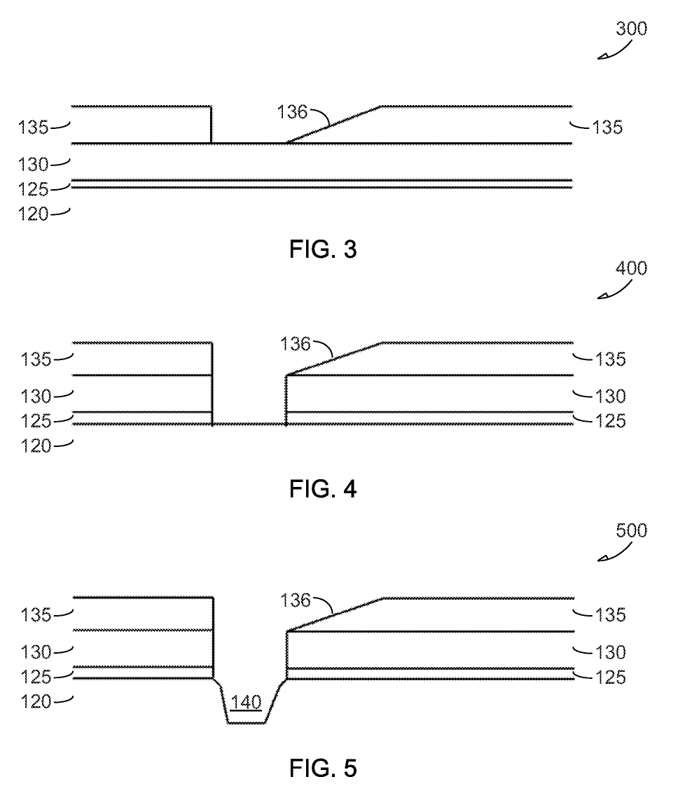

FIG. 2 illustrates generally an example of an asymmetrically sloped STI region 115 of an LDMOS device 200. In other examples, the LDMOS device 100 can include one or more other devices having an STI region. In an example, a first sidewall 116 (e.g., proximate the drain of the device) can include a steep sidewall, and a second sidewall 117 (e.g., proximate the source of the device) can include a relatively shallower, asymmetrically sloped wall (e.g., in contrast to the first sidewall 116).

In an example, the second sidewall 117 can be defined as a series of substantially continuous linear sidewall regions having different slopes. In an example, each successive region, from the base of the trench to the surface of the substrate, can have a decreasing slope. For example, the second sidewall 117 can include a single, continuous, asymmetrically sloped sidewall having two or more regions, including:

(1) a first region 118 proximate the base of the trench, or proximate an edge of the base of the trench, having a first slope; and

(2) a second region 119 proximate the surface of the substrate having a second slope lower than the first slope.

In an example, one or more of the regions of the second sidewall 117 can include a non-linear region (e.g,, a curved region). In other examples, the second sidewall 117 can include more than two regions. Further, in certain examples, the slope of one or more of successive regions of the second sidewall can either increase or decrease relative to proximate regions.

In an example, the length of the first region 118 (e.g., the height of the first region, from the base of the trench to the base of the second region) and the length of the second region 119 (e.g., the height of the second region, from the top of the first region to the working top surface of the substrate) can each be longer than one-tenth of the depth of the asymmetrically sloped STI region 115. In other examples, the length of one or more of the first and second regions 118, 119 can be longer than one-fifth of the depth of the asymmetrically sloped STI region 115.

### Fabrication Examples

In an example, to fabricate the asymmetric STI region, a photolithography pattern can be defined with a dithered edge on a source side of the isolation region where dithering increases open area towards the open region defining the trench of the STI region. The mask dithering (e.g., dithering masking chrome layers) can be required to “thin” the resist toward the trench region following developing. In contrast, other fabrication processes can include using phase shifting masks having different thickness glass or crystalline quartz uncovered by a chrome mask.

Further, dry etching can be used to form the asymmetrical STI region, including a multi-step etch with one or more “break-through” etching steps designed to etch silicon nitride. The etching process can be carried out on a steady-state silicon etcher, on a time division multiplexed (TDM) silicon etcher, or on one or more other compatible etchers.

Wet etching or cleaning can be performed prior to thermal liner oxidation. The time can be critical in controlling transistor leakage or subthreshold slope, for example, in typical logic circuits. Further, intermediate processing requiring wet etching of oxides or oxynitrides can be necessary to smooth STI region sidewalls.

Thermal oxidation of one or more of the STI region sidewall can be performed to smooth or round the intermediate corners of the trench. In an example, oxides (and in certain examples, only oxides) can be used for intermediate steps, while oxides or oxynitrides can be used for STI region liner prior to high density plasma (HDP) deposition. The thermal oxidation can be carried out using furnaces or rapid thermal processing (RPT) tools.

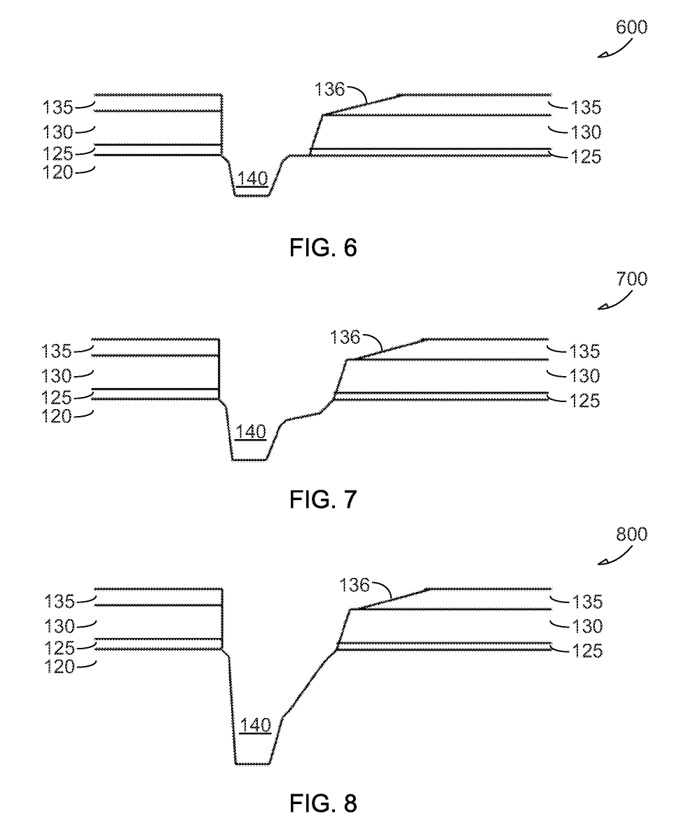

FIGS. 3-8 illustrate generally example fabrication steps for forming an asymmetrically sloped STI region on a device including a silicon substrate 120, a pad oxide layer 125, an isolation nitride layer 130, and a patterned photoresist layer 135.

FIG. 3 illustrates generally an example of a device 300 post photolithography exposure, baking, and developing, the device 100 having a sloped line 136 on a source edge of the patterned photoresist layer 135.

FIG. 4 illustrates generally an example of a device 100 post dry etch of the isolation nitride layer 130 and post etch of the pad oxide layer 125. In an example, one or more of the isolation nitride layer 130 or the pad oxide layer 125 etch can be performed insitu to a silicon etcher.

FIG. 5 illustrates generally an example of a device 100 following an initial etch of the silicon substrate 120. In an example, the initial etch of the silicon substrate 120 can be controlled by time, and, in certain examples, multiple etch steps can be used to provide an STI region 140.

FIG. 6 illustrates generally an example of a device 100 following a first cycle of O2 plasma/nitride chemistry/oxide etch chemicals, further shaping the STI region 140.

FIG. 7 illustrates generally an example of a device 100 following continued bulk silicon trench etch, further defining the STI region 140. In an example, multiple etch steps can be used.

FIG. 8 illustrates generally an example of a device 100 post STI region 140 etch processing. The STI region 140 of FIG. 8 includes a continuous, asymmetrically sloped STI region. In an example, the device 100 of FIG. 8 can be ready for resist strip, liner pre-clean thermal liner oxidation, etc.

### Additional Notes and Examples

In Example 1, a semiconductor device includes a substrate including a semiconductor region defining a working top surface in which the semiconductor device is formed, a drain region, a source region, and a shallow trench isolation (STI) region in the substrate between the drain region and the source region, the STI region including a continuous, asymmetrically sloped sidewall.

In Example 2, the continuous, asymmetrically sloped sidewall of Example 1 optionally includes a first region proximate the base of the STI region having a first slope and a second region proximate the top surface of the substrate having a second slope, the second slope different than the first slope.

In Example 3, the first slope of any one or more of Examples 1-2 is optionally substantially constant along the first region, and the second slope of any one or more of Examples 1-2 is optionally substantially constant along the second region.

In Example 4, the STI region of any one or more of Examples 1-3 optionally includes a depth from the top surface of the substrate to the base of the STI region, and wherein each of the first and second regions of the continuous, asymmetrically sloped sidewall are greater than one-tenth of the depth of the STI region.

In Example 5, each of the first and second regions of the continuous, asymmetrically sloped sidewall of any one or more of Examples 1-4 are optionally greater than one-fifth of the depth of the STI region.

In Example 6, the depth of the STI region of any one or more of Examples 1-5 optionally substantially corresponds to the sum of the lengths of the first and second regions of the continuous, asymmetrically sloped sidewall.

In Example 7, the STI region of any one or more of Examples 1-6 optional v includes a first non-asymmetrically sloped sidewall having a substantially linear slope and a second asymmetrically sloped sidewall.

In Example 8, the first asymmetrically sloped sidewall of any one or more of Examples 1-7 is optionally proximate the source region and the second non-asymmetrically sloped sidewall is proximate the drain region.

In Example 9, the semiconductor device of any one or more of Examples 1-8 optionally includes a metal oxide semiconductor field effect transistor (MOSFET).

In Example 10, the semiconductor device of any one or more of Examples 1-9 optionally includes a lateral double-diffused field metal oxide semiconductor (LDMOS) device.

In Example 11, a semiconductor device includes a shallow trench isolation (STI) region in a stibstrate between a drain region and a source region of the semiconductor device, the STI region including first and second sidewall, the first sidewall proximate the drain region and the second sidewall proximate the source region, wherein the second sidewall includes a continuous, asymmetrically sloped sidewall having at least two regions with different slopes with respect to atop surface of the substrate.

In Example 12, the continuous, asymmetrically sloped sidewall of any one or more of Examples 1-11 optionally includes a first region proximate the base of the STI region having a first slope, and a second region proximate the top surface of the substrate having a second slope, the second slope different than the first slope.

In Example 13, the first slope of any one or more of Examples 1-12 is optionally substantially constant along the first region, and wherein the second slope is substantially constant along the second region.

In Example 14, the STI region of any one or more of Examples 1-13 optionally includes a depth from the top surface of the substrate to the base of the STI region, and wherein each of the first and second regions of the continuous, asymmetrically sloped sidewall are greater than one-tenth of the depth of the STI region.

In Example 15, each of the first and second regions of the continuous, asymmetrically sloped sidewall of any one or more of Examples 1-14 are optionally greater than one-fifth of the depth of the STI region.

In Example 16, the depth of the STI region of any one or more of Examples 1-15 optionally substantially corresponds to the sum of the lengths of the first and second regions of the continuous, asymmetrically sloped sidewall.

In Example 17, the first sidewall of any one or more of Examples 1-16 optionally includes a non-asymmetrically sloped sidewall having a substantially linear slope.

In Example 18, the semiconductor device of any one or more of Examples 1-17 optionally includes a metal oxide semiconductor field effect transistor (MOSFET).

In Example 19, the semiconductor device of any one or more of Examples 1-18 optionally includes a lateral double-diffused field metal oxide semiconductor (LDMOS) device.

In Example 20, a semiconductor device includes a substrate including a semiconductor region defining a working top surface in which the semiconductor device is formed, a drain region, a source region, and a shallow trench isolation (STI) region in a substrate between the drain region and the source region, the STI region including first and second sidewalls, the first sidewall proximate the drain region and the second sidewall proximate the source region, wherein the second sidewall includes a continuous, asymmetrically sloped sidewall including a first region having a first slope substantially constant along the first region and a second region having a second slope substantially constant along the second region, wherein the first slope is different than the second slope, and wherein the STI region includes a depth from the working top surface of the substrate to the base of the STI region, and wherein each of the first and second regions have a depth greater than one-fifth of the depth of the STI region.

In Example 21, a system or apparatus can include, or can optionally be combined with any portion or combination of any portions of any one or more of Examples 1-20 to include, means for performing any one or more of the functions of Examples 1-20, or a machine-readable medium including instructions that, when performed by a machine, cause the machine to perform any one or more of the functions of Examples 1-20.

The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, although the examples above have been described relating to PNP devices, one or more examples can be applicable to NPN devices. In other examples, the above-described examples (or one or more aspects thereof) may be used in combination with each other. Other embodiments can be used, such as by one of ordinary skill in the art upon reviewing the above description. The Abstract is provided to comply with 37 C,F,R, §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

What is claimed is:

1. A semiconductor device, comprising:
a substrate including a semiconductor region defining a working top surface in which the semiconductor device is formed;
a drain region;
a source region; and
a shallow trench isolation (STI) region in the substrate between the drain region and the source region, the STI region including a continuous, asymmetrically sloped sidewall.

2. The semiconductor device of claim 1, wherein the continuous, asymmetrically sloped sidewall includes a first region proximate the base of the STI region having a first slope and a second region proximate the top surface of the substrate having a second slope, the second slope different than the first slope.

3. The semiconductor device of claim 2, wherein the first slope is substantially constant along the first region, and wherein the second slope is substantially constant along the second region.

4. The semiconductor device of claim 2, wherein the STI region includes a depth from the top surface of the substrate to the base of the STI region, and wherein each of the first and second regions of the continuous, asymmetrically sloped sidewall are greater than one-tenth of the depth of the STI region.

5. The semiconductor device of claim 4, wherein each of the first and second regions of the continuous, asymmetrically sloped sidewall are greater than one-fifth of the depth of the STI region.

6. The semiconductor device of claim 5, wherein the depth of the STI region substantially corresponds to the sum of the lengths of the first and second regions of the continuous, asymmetrically sloped sidewall.

7. The semiconductor device of claim 1, wherein the STI region includes a first non-asymmetrically sloped sidewall having a substantially linear slope and a second asymmetrically sloped sidewall.

8. The semiconductor device of claim 7, wherein the first asymmetrically sloped sidewall is proximate the source region and the second non-asymmetrically sloped sidewall is proximate the drain region.

9. The semiconductor device of claim 1, wherein the semiconductor device includes a metal oxide semiconductor field effect transistor (MOSFET).

10. The semiconductor device of claim 1, wherein the semiconductor device includes a lateral double-diffused field metal oxide semiconductor (LDMOS) device.

11. A semiconductor device, comprising:
a shallow trench isolation (STI) region in a substrate between a drain region and a source region of the semiconductor device, the STI region including first and second sidewall, the first sidewall proximate the drain region and the second sidewall proximate the source region, wherein the second sidewall includes a continuous, asymmetrically sloped sidewall having at least two regions with different slopes with respect to a top surface of the substrate.

12. The semiconductor device of claim 11, wherein the continuous, asymmetrically sloped sidewall includes a first region proximate the base of the STI region having a first slope, and a second region proximate the top surface of the substrate having a second slope, the second slope different than the first slope.

13. The semiconductor device of claim 12, wherein the first slope is substantially constant along the first region, and wherein the second slope is substantially constant along the second region.

14. The semiconductor device of claim 12, wherein the STI region includes a depth from the top surface of the substrate to the base of the STI region, and wherein each of the first and second regions of the continuous, asymmetrically sloped sidewall are greater than one-tenth of the depth of the STI region.

15. The semiconductor device of claim 14, wherein each of the first and second regions of the continuous, asymmetrically sloped sidewall are greater than one-fifth of the depth of the STI region.

16. The semiconductor device of claim 15, wherein the depth of the STI region substantially corresponds to the sum of the lengths of the first and second regions of the continuous, asymmetrically sloped sidewall.

17. The semiconductor device of claim 11, wherein the first sidewall includes a non-asymmetrically sloped sidewall having a substantially linear slope.

18. The semiconductor device of claim 11, wherein the semiconductor device includes a metal oxide semiconductor field effect transistor (MOSFET).

19. The semiconductor device of claim 11, wherein the semiconductor device includes a lateral double-diffused field metal oxide semiconductor (LDMOS) device.

20. A semiconductor device, comprising:
a substrate including a semiconductor region defining a working top surface in which the semiconductor device is formed;
a drain region;
a source region; and
a shallow trench isolation (STI) region in a substrate between the drain region and the source region, the STI region including first and second sidewall, the first sidewall proximate the drain region and the second sidewall proximate the source region, wherein the second sidewall includes a continuous, asymmetrically sloped sidewall including a first region having a first slope substantially constant along the first region and a second region having a second slope substantially constant along the second region, wherein the first slope is different than the second slope, and wherein the STI region includes a depth from the working top surface of the substrate to the base of the STI region, and wherein each of the first and second regions have a depth greater than one-fifth of the depth of the STI region.
